(19) United States
(12) Patent Application Publication
(10) Pub. No.: US 2004/0132242 A1
(43) Pub. Date: Jul. 8, 2004

(54) Method for the production of one-dimensional nanostructures and nanostructures obtained according to said method

(76) Inventors: Marie D'Angelo, Paris (FR); Victor Aristov, Orsay (FR); Vincent Derycke, Auverique (FR); Fabrice Semond, Mougins Le Haut (FR); Patrick Soukiassian, Chevreuse (FR)

Correspondence Address: OBLON, SPIVAK, MCCLELLAND, MAIER & NEUSTADT, P.C., 1940 DUKE STREET, ALEXANDRIA, VA, 22314, US

(21) Appl. No.: 10/475,269

(22) PCT Filed: Apr. 17, 2002
(86) PCT No.: PCT/FR02/01326

(30) Foreign Application Priority Data
Apr. 19, 2001 (FR) 01/05314

(51) Int. Cl. H01L 21/8238

(52) U.S. Cl. 438/200

(57) ABSTRACT

According to the invention, parallel atomic lines (4) are formed on the surface of a substrate (2) in silicon carbide, and a material is deposited on this surface, able to be adsorbed selective fashion between the atomic lines and not on these atomic lines, the depositing of this material thereby generating strips (6,8) of this material between the atomic lines.

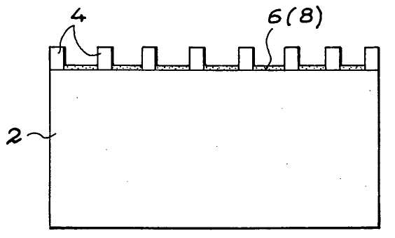

The invention particularly applies to the fabrication of nanostructures having passivated or metallized strips.

The present invention concerns a method for fabricating unidimensional nanostructures and nanostructures obtained with this method.

With the invention it is possible in particular to fabricate nanostructures having passivated or metallized strips.

The invention particularly applies to the area of nanoelectronics.

### PRIOR ART

A method is already known for fabricating unidimensional nanostructures, also called “atomic lines”, on the surface of a substrate in silicon carbide (SiC) through the following document to which reference will be made:

[1] International application PCT/FR 97/02298 publication n^{o} WO 98/27578 entitled “Fils atomiques de grande longueur et de grande stabilité, procédé de fabrication de ces fils, application en nanoélectronique”, invention by G. Dujardin, A. Mayne, F. Semond and P. Soukiassian.

Reference will also be made to the following document:

[2] P. Soukiassian et al. Phys. Rev. Lett. 79 2498 (1997).

### DISCLOSURE OF THE INVENTION

The present invention solves the problem relating to the fabrication of unidimensional nanostructures having a pre-defined electric state, namely an electrically insulating or conductor state.

In particular, the invention sets out to fabricate insulating or conductor unidimensional structures of long length and wide width on nanometric scale.

The length of these structures, or strips, is likely to exceed 1 micrometer and their width may be adjusted within a range extending from 1 nm to 10 nm.

More precisely, the subject of the present invention is a method for fabricating unidimensional nanostructures, this method being characterized in that:

parallel atomic lines are formed on the surface of a substrate in silicon carbide, and

a material is deposited on this surface, able to be selectively adsorbed between the atomic lines and not on these atomic lines, the deposition of this matter thereby generating strips of this material between the atomic lines.

Preferably, the atomic lines are in silicon.

According to one preferred embodiment of the method of the invention, the silicon carbide has a cubic structure and the surface is a surface of the cubic silicon carbide substrate.

According to one particular embodiment of the method of the invention, the material is chosen so as to generate passivated strips.

In this case, the material may be hydrogen or oxygen or any other molecule with which it is possible to passivate the underlying surface, for example NO, N₂O, N₂, NH₃ and sulphur.

According to a second particular embodiment of the method of the invention, the material is chosen so as to generate electrically conductive strips.

In this case, the material is a metal for example. This metal may be silver for example or any other metal, e.g. gold, copper or a metal chosen from the group of alkaline metals or transition metals.

According to other particular embodiments of the method of the invention, the material is formed of organic molecules or inorganic molecules.

The present invention also concerns nanostructures obtained with the method of the invention.

### SHORT DESCRIPTION OF THE FIGURE

The present invention will be better understood on reading the description of the particular embodiments set out below, given solely for illustration purposes and which are in no way restrictive, with reference to the appended single FIGURE which is a cross section diagram of nanostructures obtained in accordance with the invention.

### DETAILED DESCRIPTION OF PARTICULAR EMBODIMENTS

A first example is now given of the method of the invention, enabling the fabrication of passivated unidimensional nanostructures.

To fabricate such nanostructures, a silicon substrate 2 is used (FIGURE) which has been treated so that its surface is a c(4×2) surface on which lie self-organized, silicon atomic lines 4 which are parallel.

Reference is made to document [1] in which it is explained how to obtain rectilinear chains of Si—Si dimers (atomic lines) on the surface of a monocrystalline substrate of SiC in β-SiC (100) cubic phase which has been transformed so that its surface is terminated 3×2 and then which has been suitably annealed.

Subsequently, through heat annealing treatments at 1100° C., this surface with 3×2 symmetry is transformed until its organisation on atomic scale has c(4×2) symmetry (reconstruction).

This surface is then exposed to ultra pure molecular hydrogen at low pressure (approximately 10⁻⁸ hPa) while maintaining the surface at room temperature (approximately 20° C.).

It is specified that the surface is exposed to molecular hydrogen until saturation (greater than 50 L). This saturation may be controlled by STM i.e. Scanning Tunnelling microscopy.

The atomic lines 4 do not react with the hydrogen whereas the underlying surface is passivated.

The hydrogen is therefore solely adsorbed between the atomic lines and thereby generates passivated strips 6 between these atomic lines.

It is to be noted that oxygen can be used instead of hydrogen.

A second example is now given of the method of the invention, with which it is possible to fabricate metallized unidimensional nanostructures.

The latter are metal strips of nanometric width made on the (100) surface of a substrate in cubic SiC.

The surface's property of self-organization is used to form atomic lines of silicon lying on a complete plane of silicon atoms. The distance between these lines may be modulated by precise annealing operations of the SiC substrate in an ultravacuum.

Potassium atoms are then deposited on this surface. The potassium metallizes the space lying between the silicon lines without metallizing the lines themselves. In this way metal strips are formed of adjustable width which are separated by atomic lines.

More precisely, the first step in the fabrication of these metallic “nanostrips” consists of preparing and calibrating a potassium source. The procedure to be followed is given below.

A source of potassium atoms is placed in an ultravacuum chamber and degassed in very precise manner. The source is considered to be sufficiently degassed when the pressure increase in the chamber during the time needed to evaporate a monolayer of potassium does not exceed 2×10⁻⁹ Pa.

The potassium source must then be calibrated. Any method may be used allowing determination of the rate of evaporation of the potassium atoms.

For example, it is possible to prepare a (100) surface of cubic SiC that is entirely made up of silicon atoms having a reconstruction of c(4×2) type, and to examine the changes in the intensity of the XPS signal derived from core level K3p.

This intensity increases and then saturates when the quantity of potassium is exactly equal to a monolayer.

Low energy electron diffraction (LEED) can also be used to examine the transformation of this c(4×2) surface into a 2×3 surface then into a 2×1 surface.

A diffraction image perfectly corresponding to such a 2×3 surface corresponds to a coverage rate of ⅔ of a monolayer.

The second step is the formation of atomic lines of silicon on the SiC surface. In this respect reference is made to document [1].

The procedure to be followed is given below:

a) The sample of cubic silicon carbide (3C—SiC) is placed in a chamber, in which the prevailing pressure is less than 5×10⁻¹⁰ hPa, and heated by a current flow directly within this sample, for several hours at 650° C. then several times at 1100° C. for one minute.

b) Using a source of silicon heated to 1300° C., several monolayers of silicon are deposited on the (100) surface of cubic SiC.

c) With thermal annealings part of the deposited silicon is evaporated in controlled manner until the surface organisation on atomic scale is of 3×2 symmetry (reconstruction). This surface symmetry may be controlled by electron diffraction.

d) This 3×2 surface is made up of atomic lines of silicon that are extremely dense, lying on a surface entirely made up of silicon atoms. Further annealing operations make it possible to reduce the density of these lines in controlled manner.

The third step consists of depositing potassium atoms on this surface.

The procedure to be followed is given below.

The SiC surface comprising the atomic lines of silicon is placed at a distance of approximately 3 cm from the potassium source. Potassium atoms are then deposited on the SiC surface. These potassium atoms are preferably deposited between the atomic lines of silicon. The quantity of silicon to be deposited must correspond to the space to be filled in between the lines.

This space located between the lines corresponds to an order of c(4×2) type. The inventors have shown with the UPS/XPS technique and with the STM/STS technique that, when the surface is saturated with potassium, this order becomes 2×1 and takes on a metal character. On the other hand, the silicon lines do not become metallic, even if the surface is saturated with potassium.

Therefore, even if the quantity of deposited potassium slightly exceeds the exactly desired quantity, this is not detrimental to results: the spaces between the lines form metallic strips 8 (figure) which are separated by non-metallic atomic lines.

It is to be noted that the use of other alkaline metals, and more generally other metals, silver for example, lead to the same result.

As a general rule the fabrication of metallic nanostrips can be made with any adsorbate having the following two properties:

the adsorbate is selectively adsorbed between the silicon lines, and

the adsorbate leads to metallisation of the space located between the lines (i.e. metallisation of the c(4×2) type reconstruction of cubic SiC).

The present invention is not limited to the use of hydrogen, oxygen or metals for the formation of nanostrips between the atomic lies: materials may be used which are formed of inorganic molecules, for example halogens (F, Cl, Br, I) or sulphur, or organic molecules, e.g. polymers including conductor polymers and organic semiconductor polymers (for example PCDTA or Thiols), molecules of e.g. benzene or pentacene type, and unidimensional organic molecules, to make bridges or contacts for example.

To deposit inorganic molecules between the atomic lines, the same method is used as for oxygen for example: the surface is exposed to molecules in vacuum, or vaporisation is used (for Br, S and I for example).

To deposit organic molecules, a deposition by vacuum evaporation for example may be used.

1. Method for fabricating unidimensional nanostructures, this method being characterized in that:
parallel atomic lines (4) are formed on the surface of a substrate (2) in silicon carbide, and
a material is deposited on this surface, able to be selectively adsorbed between the atomic lines and not on these atomic lines,
the deposition of this material thereby generating strips (6,8) of this material between the atomic lines.

2. Method according to claim 1, in which the atomic lines (4) are in silicon.

3. Method according to claim 2, in which the silicon carbide has a cubic structure and the surface is a (100) surface of the cubic silicon carbide substrate.

4. Method according to any of claims 1 to 3, in which the material is chosen so as to generate passivated strips (6).

5. Method according to claim 4, in which the material is hydrogen.

6. Method according to claim 4, in which the material is oxygen or any other molecule enabling passivation of the underlying surface, for example NO, N₂O, N₂, NH₃ and sulphur.

7. Method according to any of claims 1 to 3, in which the material is chosen so as to generate electrically conductive strips (8).

8. Method according to claim 7, in which the material is a metal.

9. Method according to claim 8, in which the metal is chosen from the group of alkaline metals or transition metals.

10. Method according to claim 8, in which the metal is silver or gold or copper.

11. Method according to any of claims 1 to 3, in which the material is formed of organic molecules, for example polymers, molecules of benzene or pentacene type and unidimensional organic molecules.

12. Method according to any of claims 1 to 3, in which the material is formed of inorganic molecules, for example halogens or sulphur.

13. Nanostructures obtained with the method according to any of claims 1 to 12.
